(19) United States
(12) Patent Application Publication
(10) Pub. No.: US 2024/0203702 A1
(43) Pub. Date: Jun. 20, 2024

(54) SUBSTRATE PROCESSING APPARATUS

(71) Applicant: SAMSUNG ELECTRONICS CO., LTD., SUWON-SI (KR)

(72) Inventors: SUNGIK PARK, Suwon-si (KR); Yongsu Jang, Cheonan-si (KR); Seungpil Chung, Cheonan-si (KR); Jungyoon Yang, Cheonan-si (KR); Inseong Lim, Cheonan-si (KR)

(73) Assignee: SEMES CO., LTD., Cheonan-si (KR)

(21) Appl. No.: 18/545,919

(22) Filed: Dec. 19, 2023

(30) Foreign Application Priority Data
Dec. 20, 2022 (KR) 10-2022-0179810

(51) Int. Cl. H01J 37/32; H01L 21/67

(52) U.S. Cl. CPC H01J 37/32522; H01J 37/32192; H01L 21/67109; H01J 2237/2001

(57) ABSTRACT

A substrate processing apparatus includes a process chamber including a processing space, a heater located inside the process chamber and configured to heat a lower portion of the processing space, and a first heat source located inside the process chamber and spaced apart from the heater and configured to heat an upper portion of the processing space, a plurality of first protrusions protruding in a vertical direction from an upper surface of the heater, and a second protrusion protruding in the vertical direction from an edge portion of the upper surface of the heater.

### CROSS-REFERENCE TO RELATED APPLICATION

This application is based on and claims priority under 35 U.S.C. § 119 to Korean Patent Application No. 10-2022-0179810, filed on Dec. 20, 2022, in the Korean Intellectual Property Office, the disclosure of which is incorporated by reference herein in its entirety.

### TECHNICAL FIELD

The inventive concept relates to a substrate processing apparatus, and more particularly, to a substrate processing apparatus applying heat to a substrate.

### DESCRIPTION OF RELATED ART

In general, semiconductor devices may be manufactured from substrates such as wafers. Specifically, a semiconductor device may be manufactured by performing a series of processes, including for example, a deposition process, a photolithography process, an etching process, and forming a fine circuit pattern on an upper surface of a substrate.

In some cases, heat may be applied to the substrate while one or more of the above processes are performed. Heat may be related to various defects in the substrate.

### SUMMARY

The inventive concept provides a substrate processing apparatus that may reduce or minimize a particle defect that may be caused by heat applied to a substrate.

According to an aspect of the inventive concepts, there is provided a substrate processing apparatus including a process chamber including a processing space, a heater located inside the process chamber and configured to heat a lower portion of the processing space, and a first heat source located inside the process chamber and spaced apart from the heater and configured to heat an upper portion of the processing space, a plurality of first protrusions protruding in a vertical direction from an upper surface of the heater, and a second protrusion protruding in the vertical direction from an edge portion of the upper surface of the heater.

According to another aspect of the inventive concepts, there is provided a substrate processing apparatus including a process chamber comprising a processing space, a microwave application unit located in an upper portion of the processing space, and a heater located inside the process chamber and configured to heat a lower portion of the processing space, wherein the heater includes a body extending in a horizontal direction, a plurality of first protrusions protruding in a vertical direction from an upper surface of the body, and a second protrusion protruding in the vertical direction from an edge portion of the upper surface of the body, the second protrusion defines a central portion of the body and an outer portion of the body opposite to the central portion when viewed from the vertical direction, and the body has a recess 1 formed in the upper surface of the body in the outer portion of the body.

According to another aspect of the inventive concepts, there is provided a substrate processing apparatus including a process chamber including a processing space for processing a substrate therein, a heater located inside the process chamber and configured to support and heat a lower surface of the substrate, wherein the heater comprises a body extending in a horizontal direction, a gas supply unit configured to supply a processing gas to the processing space, a microwave application unit configured to heat the processing gas supplied to the processing space, a plurality of first protrusions protruding in a vertical direction from an upper surface of the body, and a second protrusion protruding in the vertical direction from an edge portion of the upper surface of the body, the second protrusion defines a central portion of the body and an outer portion of the body opposite to the central portion when viewed from the vertical direction, the second protrusion has a ring shape when viewed from the vertical direction, the body has a recess formed in the upper surface of the body in the outer portion of the body, and the recess has a ring shape when viewed from the vertical direction.

### BRIEF DESCRIPTION OF THE DRAWINGS

Embodiments will be more clearly understood from the following detailed description taken in conjunction with the accompanying drawings in which:

FIG. 1 is a schematic cross-sectional view of a substrate processing apparatus according to some embodiments;

FIG. 2 is a cross-sectional view showing a portion AA of the substrate processing apparatus according to some embodiments;

FIG. 3 is a plan view schematically illustrating a heater of the substrate processing apparatus of FIG. 1;

FIG. 4 is a cross-sectional view showing the portion AA of a substrate processing apparatus according to some embodiments;

FIG. 5 is a plan view schematically illustrating a heater according to some embodiments;

FIG. 6 is a plan view schematically illustrating a heater according to some embodiments;

FIG. 7 is a cross-sectional view showing the portion AA of a substrate processing apparatus according to some embodiments;

FIG. 8A, FIG. 8B, and FIG. 8C are cross-sectional views illustrating the portion AA of a substrate processing apparatus according to some embodiments; and

FIG. 9 is a schematic cross-sectional view of a substrate processing apparatus according to some embodiments.

### DETAILED DESCRIPTION

Hereinafter, embodiments of the inventive concept will be described in detail with reference to the accompanying drawings. The same reference numerals are used for the same components in the drawings, and redundant descriptions thereof may be omitted.

Particle defects, such as hardware-induced surface defects, in semiconductor manufacturing may have various causes. The inventive concept provides a substrate processing apparatus that may reduce or minimize a particle defect that may be caused by heat applied to a substrate.

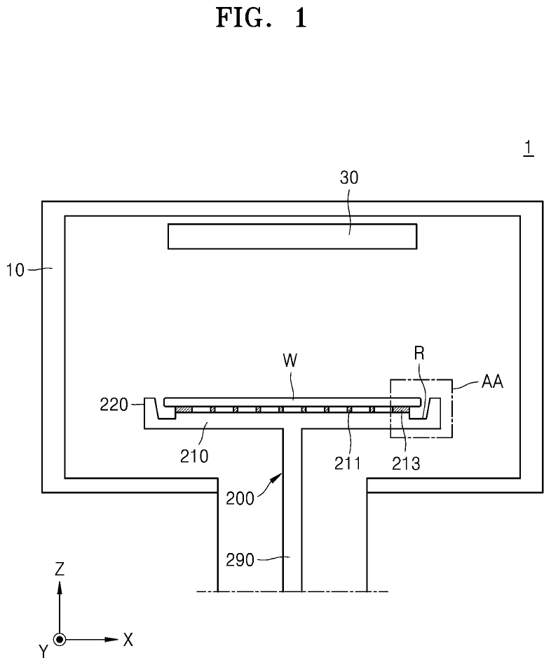

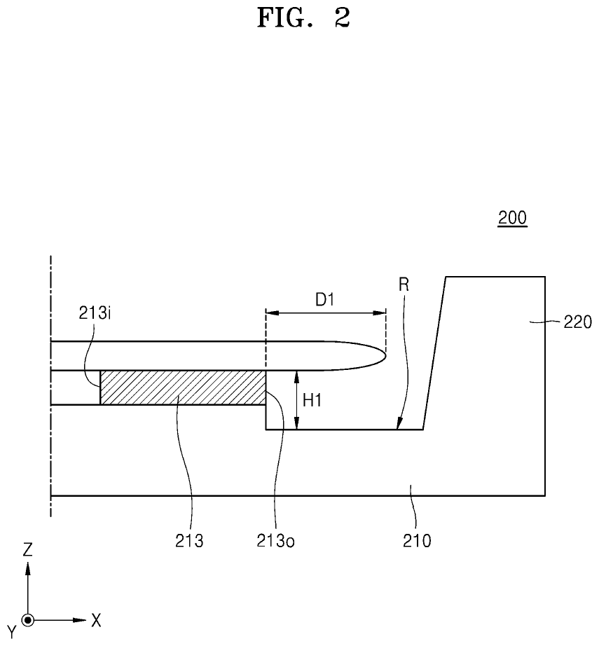

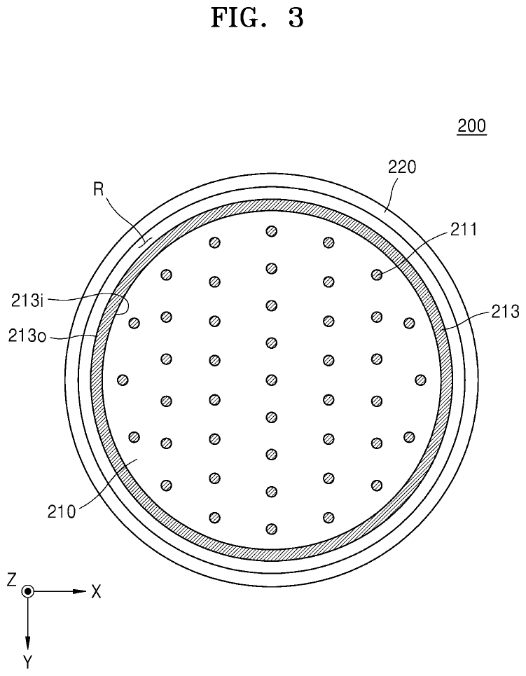

FIG. 1 is a schematic cross-sectional view of a substrate processing apparatus according to some embodiments. FIG. 2 is a cross-sectional view showing a portion AA of the substrate processing apparatus according to some embodiments. FIG. 3 is a plan view schematically illustrating a heater of the substrate processing apparatus of FIG. 1.

Referring to FIG. 1, FIG. 2, and FIG. 3, a substrate processing apparatus 1 may include a process chamber 10, a heater 200, and a first heat source 30. A processing space processing a substrate W may be formed inside the process chamber 10. A vertical cross-section of the process chamber 10 may have a rectangular shape, but is not limited thereto.

Processing of the substrate W may be performed inside the process chamber 10. The processing may include a plurality of processes, including for example, a deposition process of the substrate W, a photolithography process, and an etching process.

The heater 200 may be located inside the process chamber 10. According to some embodiments, the heater 200 may be located at a bottom portion inside the process chamber 10. The heater 200 may support the substrate W. The heater 200 may be located inside the process chamber 10 and configured to heat a lower portion of the processing space. The heater 200 may be configured to apply heat to a lower surface of the substrate W while supporting the lower surface of the substrate W.

In the drawings, an X-axis direction and a Y-axis direction may be parallel to the lower surface of the substrate W and may be perpendicular to each other. A Z-axis direction may be perpendicular to the lower surface of the substrate W. In other words, the Z-axis direction may be perpendicular to the X-Y plane.

Also, in the drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

The heater 200 may include a body 210 and a support 290. The body 210 may support the lower surface of the substrate W. In some embodiments, a vertical cross-section of the body 210 may have a shape extending in the first horizontal direction or the second horizontal direction. The body 210 may have a disc shape when viewed in the vertical direction Z.

A heating member, such as a hot wire, may be disposed inside the body 210. The hot wire may heat the body 210 to increase a temperature of the body 210. The body 210, heated by the hot wire, may increase a temperature of the substrate W while supporting the substrate W.

The support 290 may be coupled to the lower surface of the body 210 to support the body 210. In some embodiments, the support 290 may have a pillar shape or a rod shape extending in the vertical direction Z.

The body 210 may include a first protrusion 211, a second protrusion 213, and a guide wall 220. The first protrusion 211 may protrude from an upper surface of the body 210 in the vertical direction Z. According to some embodiments, the first protrusion 211 may have a cylindrical shape extending in the vertical direction Z, but is not limited thereto. The first protrusion 211 may have other shapes, such as a prismatic shape extending in the vertical direction Z.

A plurality of first protrusions 211 may be provided. Upper surfaces of the first protrusions 211 may contact the lower surface of the substrate W. That is, the lower surface of the substrate W may contact the plurality of first protrusions 211.

The second protrusion 213 may protrude from an edge portion of the upper surface of the body 210 in the vertical direction Z. The second protrusion 213 may include an inner side 213i disposed toward a center of the body 210 when viewed in the vertical direction Z, and an outer side 2130 disposed opposite to the inner side 213i. That is, the second protrusion 213 may have the shape of a wall protruding in the vertical direction Z along the edge portion of the upper surface of the body 210. According to some embodiments, the second protrusion 213 may have a ring shape when viewed in the vertical direction Z.

An upper surface of the second protrusion 213 may contact an outer portion of the lower surface of the substrate W. Accordingly, the substrate W may contact both the upper surface of the first protrusion 211 and the upper surface of the second protrusion 213.

According to some embodiments, the first protrusion 211 may be formed on the upper surface of the body 210 on an inner side 213i of the second protrusion 213. That is, when viewed in the vertical direction Z, the first protrusion 211 may be formed within an area defined by the inner side 213i of the second protrusion 213. Accordingly, a central portion of the lower surface of the substrate W may be supported by the first protrusion 211, and an outer portion of the substrate W may be supported by the second protrusion 213. However, the inventive concept is not limited thereto, and the first protrusion 211 may be additionally formed on the outer portion of the second protrusion 213. That is, when viewed in the vertical direction Z, the first protrusion 211 may be formed outside of a shape formed by the outer side 2130 of the second protrusion 213.

The guide wall 220 may be formed along a circumference of the body 210 on the outermost part of the body 210. The guide wall 220 may prevent the substrate W supported by the first protrusion 211 and the second protrusion 213 from moving in the horizontal direction X or in the horizontal direction Y and away from the heater 200.

According to some embodiments, an outer wall of the guide wall 220 may have a shape extending in the vertical direction Z and an inner wall thereof may have a slope extending in the vertical direction toward the outer wall.

The body 210 may have a first recess R formed in the upper surface of the body 210. The first recess R may be formed outside an outermost protrusion contacting the substrate W. According to some embodiments, the first recess R may be formed outside the second protrusion 213 in the upper surface of the body 210.

According to some embodiments, the first recess R may have a ring shape when viewed in the vertical direction Z. In other words, when viewed in the vertical direction Z, the first recess R may have a donut shape defining an inner circle and an outer circle.

The first recess R may be formed at a position where a portion of the first recess R may underlie a portion of the substrate W in the vertical direction Z. The substrate W may be formed at a position where a portion of the substrate W may overlap a portion of the first recess R in the vertical direction Z. According to some embodiments, the outer side 2130 of the second protrusion 213 may be spaced apart from the guide wall 220 in the horizontal direction with the first recess R disposed therebetween.

The first heat source 30 may be configured to apply heat to the upper surface of the substrate W. The first heat source 30 may be disposed inside the process chamber 10. The first heat source 30 may be configured to heat an upper portion of the processing space. The first heat source 30 may be disposed inside the processing space formed inside the process chamber 10. According to some embodiments, the first heat source 30 may be spaced apart from the substrate W in the vertical direction Z so as to face the upper surface of the substrate W.

As the substrate W is disposed on the heater 200 of the process chamber 10, the lower surface of the substrate W may be heated by the heater 200. the lower surface of the substrate W may be heated by the first protrusion 211 and the second protrusion 213, which contact the lower surface of the substrate W.

A side surface of the substrate W may be spaced apart from the guide wall 220. The side surface of the substrate W may be exposed to an airflow. Due to the airflow, heat loss may be greater in a side portion of the substrate W and the outer portion of the substrate W than in the central portion thereof. Therefore, the temperature of the outer portion of the substrate W may be lower than the temperature of the central portion of the substrate W.

In the substrate processing apparatus 1 of the inventive concept, the central portion of the substrate W may be supported by the first protrusion 211 and the outer portion thereof may be supported by the second protrusion 213. The second protrusion 213 may support the outer portion of the substrate W in a wall shape having the inner side 213i and the outer side 2130. The second protrusion 213 having the wall shape may have a large contact area with the substrate W. That is, an area of the outer portion of the substrate W contacting the second protrusion 213 may be increased by the wall shape, and accordingly, heat applied to the outer portion of the substrate W may be increased.

Therefore, even if heat loss occurs in the outer portion of the substrate W is greater than in the central portion thereof, for example, due to airflow, the heat applied to the outer portion of the lower surface of the substrate W by the second protrusion 213 is greater than the heat applied to the central portion of the substrate W by the first protrusion 211, and thus, the temperature of the substrate W may be uniformly maintained across the central portion and the outer portion thereof. Further, the substrate W may be heated uniformly across the central portion and the outer portion thereof. The greater heat applied to the outer portion of the substrate W by the second protrusion 213 may compensate for the greater heat loss at the outer portion.

As an amount of expansion and contraction of the substrate W may be directly proportional to a temperature change, a thermal distortion and warpage of the substrate W may depend on its thermal coefficient. A uniform heating of the substrate W may reduce or eliminate a cause of thermal distortion and warpage. Accordingly, warpage of the substrate W may be reduced or eliminated in a case where the substrate W may be heated uniformly across the central portion and the outer portion thereof.

When the temperature of the substrate W is uniformly maintained, a material deposited on the substrate W may also be deposited on the substrate W with a uniform thickness. For example, uniform deposition may be achieved in a case where warpage of the substrate W may be reduced or eliminated.

The first recess R formed outside the body 210 may prevent a particle defect that may be generated when the substrate W is deformed by heat. When the upper surface of the substrate W is heated by the first heat source 30, the substrate W may take a convex shape. For example, the substrate W may be deformed into a shape in which the outer portion of the substrate W is bent downward and the central portion thereof is bent upward. In a case where the substrate W and the body 210 collide, a particle defect may be generated, for example, due to particles generated from the substrate W being released in the process chamber 10. As the first recess R provides an extra space below the outer portion of the substrate W, even in a case where the substrate W may be deformed into the convex shape, the substrate W and the body 210 do not collide, and a particle defect that may be generated due to such a collision may be avoided, reduced, or minimized.

Similarly, in a case where the lower surface of the substrate W is heated by the heater 200 and the substrate W takes a concave shape in which the outer portion of the substrate W may be bent downward and the central portion thereof is bent upward, particles generated on the substrate W may be avoided, reduced, or minimized.

In addition, a distance H1 from the upper surface of the body 210 where the first recess R is formed to the lower surface of the substrate W may be in a range of about 25 μm (micrometers) to about 35 μm. This range is substantially that same as a distance from the upper surface of the body 210 where the recess is formed to an upper surface of the second protrusion 213.

When the first recess R is formed such that the distance H1 is in the range of about 25 μm to about 35 μm, even if the substrate W is heated by the first heat source 30 or the heater 200 and deformed into a shape in which the uppermost portion of the substrate W is bent downward, the generation of particles may be avoided, reduced, or minimized by preventing a collision between the outermost portion of the substrate W and the body 210 of the heater 200.

In addition, when the distance H1 is within the range of about 25 μm to about 35 μm, exposure of the outer portion of the lower surface of the substrate W may be reduced or minimized. Therefore, exposure of the lower surface of the substrate W to a processing gas during a process may be eliminated or reduced.

As a result, when the distance H1 is in the range of about 25 μm to about 35 μm, particles generated due to a deformation of the substrate W may be avoided, reduced, or minimized while an exposure of the outer portion of the lower surface of the substrate W may be reduced or minimized.

A shortest straight distance DI from the outer surface of the second protrusion 213 to the side surface of the substrate W may be in a range of about 2400 μm to about 3000 μm. That is, the second protrusion 213 may be formed within the range of about 2400 μm to about 3000 μm from the side of the substrate W.

In other words, the horizontal distance from the outer surface of the second protrusion 213 to the side surface of the substrate W may be in a range of about 2400 μm to about 3000 μm. When the outer surface of the second protrusion 213 is formed at a position within the range, in a case where the substrate W may be heated by the first heat source 30 or the heater 200 and deformed into a convex shape, the generation of a particle defect may be reduced or minimized by preventing a collision between the outermost portion of the substrate W and the body 210 of the heater 200.

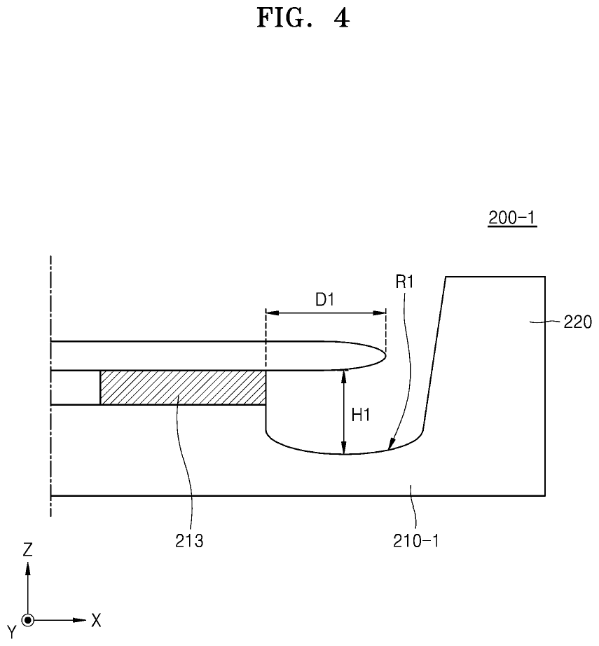

FIG. 4 is a cross-sectional view showing the portion AA of a substrate processing apparatus according to some embodiments. Hereinafter, redundant descriptions of the heater 200 described with reference to FIG. 1, FIG. 2, and FIG. 3 and a heater 200-1 of FIG. 4 may be omitted and the differences therebetween are mainly described.

Referring to FIG. 4, a body 210-1 of the heater 200-1 may include the second protrusion 213 and the guide wall 220. A second recess R1 may be formed in the outer portion of the body 210-1. According to some embodiments, the second recess R1 may have a concave parabolic shape. Accordingly, a vertical cross-section of the body 210-1 in which the second recess R1 is formed may have a concave upper surface.

When the second recess R1 has the concave shape, even if the substrate W is bent in the direction of the second recess R1 due to deformation of the substrate W, the substrate W may not contact the body 210-1 of a part where the second recess R1 is formed, and thus, a particle defect may be avoided, reduced, or minimized. For example, particles may not be generated from the substrate W in case where a collision may be prevented, and thus, a particle defect can be avoided, reduced, or minimized.

At this time, a distance in the vertical direction Z from the upper surface of the body 210-1 having a low vertical level where the second recess R1 is formed to the lower surface of the substrate W may be in a range of about 25 μm to 35 about μm.

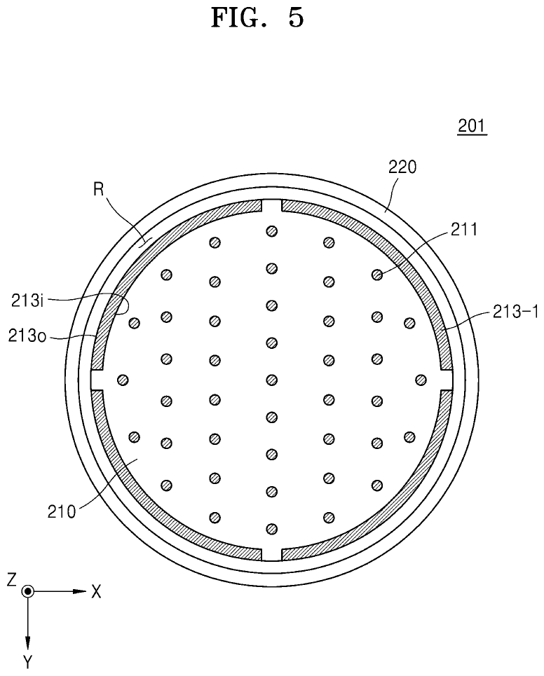

FIG. 5 is a plan view schematically illustrating a heater according to some embodiments. Hereinafter, redundant descriptions of the heater 200 described with reference to FIG. 1, FIG. 2, and FIG. 3 and a heater 201 of FIG. 5 may be omitted and the differences therebetween are mainly described.

Referring to FIG. 5, the body 210 of the heater 201 may include a second protrusion 213-1 and the guide wall 220. The second protrusion 213-1 may have a wall shape having the inner side 213i and the outer side 2130. According to some embodiments, a plurality of second protrusions 213-1 may be formed. Different ones of the second protrusions 213-1 may be spaced apart from each other by a gap. The plurality of second protrusions 213-1 may be walls having an arc shape when viewed in the vertical direction Z.

When the plurality of second protrusions 213-1 each having the arc shape are formed, an external airflow may pass through the gaps and between the plurality of second protrusions 213-1. The external airflow may flow between the lower surface of the substrate W and the upper surface of the body 210. The substrate W may be prevented from moving due to heating and expansion of gas in a space between the upper surface of the body 210 and the lower surface of the substrate W. For example, a gas disposed in the space between the upper surface of the body 210 and the lower surface of the substrate W and that has been heated may flow out through the gaps and between the plurality of second protrusions 213-1.

In addition, different regions of the outer portion of the substrate W may have different heat loss characteristics. In this case, the second protrusion 213-1 may be formed on a lower end of a region having a relatively high heat loss. The gaps between the plurality of second protrusions 213-1 may be disposed in a region having relatively low heat loss. Accordingly, the entire substrate W may be set to a uniform temperature. Further, the substrate W may be uniformly heated to a given temperature.

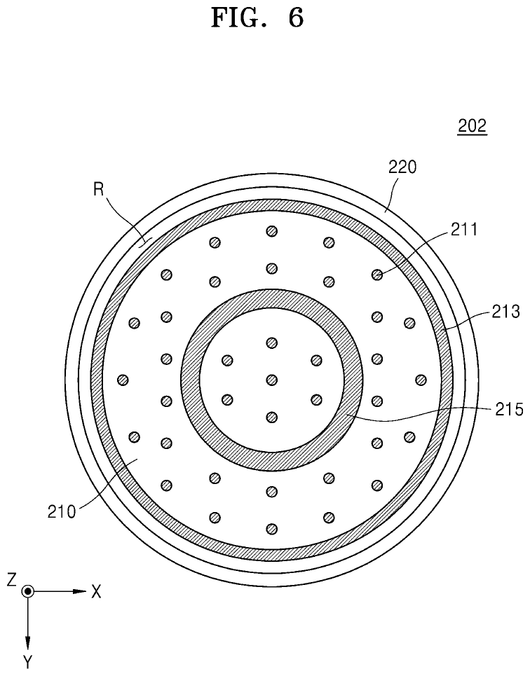

FIG. 6 is a plan view schematically illustrating a heater according to some embodiments. Hereinafter, redundant descriptions of the heater 200 described with reference to FIG. 1, FIG. 2, and FIG. 3 and a heater 202 of FIG. 6 may be omitted and the differences therebetween are mainly described.

Referring to FIG. 6, the body 210 of the heater 202 may include the second protrusion 213, a third protrusion 215, and the guide wall 220. The third protrusion 215 may be formed in the central portion of the body 210 within an area defined by the second protrusion 213. The third protrusion 215 may have a ring shape when viewed in the vertical direction Z. In other words, when viewed in the vertical direction Z, the third protrusion 215 may have a donut shape defining an inner circle and an outer circle.

At least one first protrusion 211 may be formed inside an area defined by the third protrusion 215, and may be formed in an area between the second protrusion 213 and the third protrusion 215. However, the inventive concept is not limited thereto, and the second protrusion 213 and the third protrusion 215 may be formed in the body 210, while the first protrusion 211 may be omitted.

When the third protrusion 215 is formed as described above, even when heat loss may occur in the central portion of the substrate W, the entire substrate W may be set to a uniform temperature. Further, the substrate W may be uniformly heated to a given temperature.

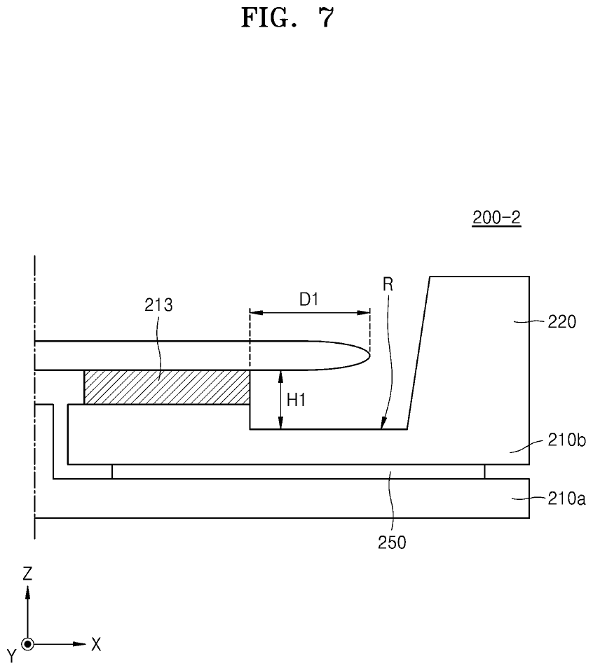

FIG. 7 is a cross-sectional view showing the portion AA of a substrate processing apparatus according to some embodiments. Hereinafter, redundant descriptions of the heater 200 described with reference to FIG. 1, FIG., and FIG. 3 and a heater 200-2 of FIG. 7 may be omitted and the differences therebetween are mainly described.

Referring to FIG. 7, the heater 200-2 may include a first body 210a and a second body 210b. The first body 210a and the second body 210b may be coupled to and separated from each other. The first body 210a may include a lower portion and a central portion of the body of the heater 200-2. The second body 210b may include an upper outer portion of the body. The coupling may be performed by a coupling pad 250.

When the first body 210a and the second body 210b are separated from each other and coupled to each other by the coupling pad 250, heat applied to the outer portion of the substrate W through the second body 210b may be reduced. Accordingly, the second body 210b may reduce heat transfer to the outer portion of the substrate W.

In addition, the coupling pad 250 may include a material having a specific coefficient of thermal conductivity. Accordingly, when the heat generated from the first body 210a is transferred to the second body 210b, the transfer of heat may be adjusted according to the specific coefficient of thermal conductivity of the coupling pad 250.

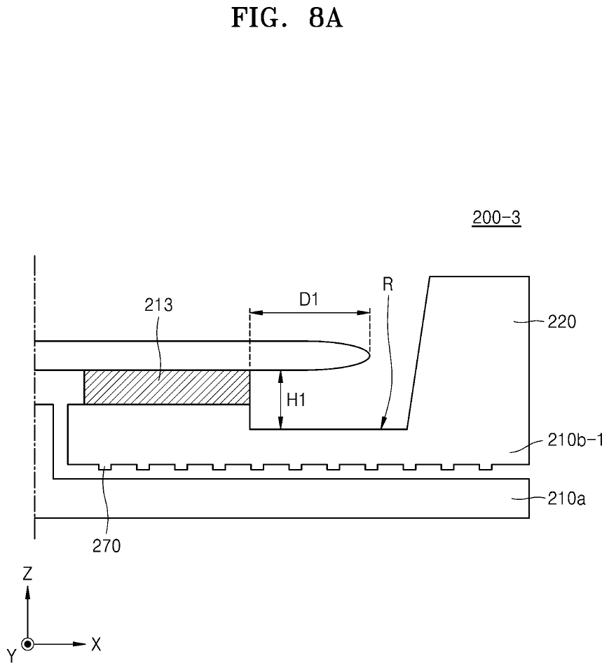

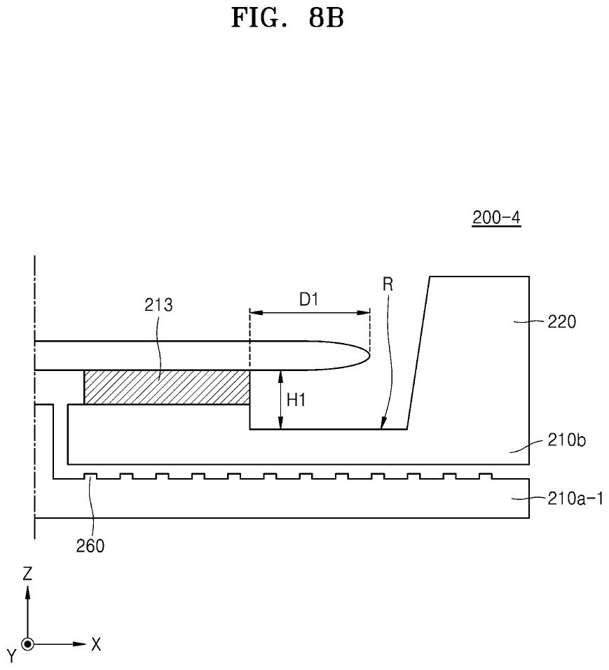

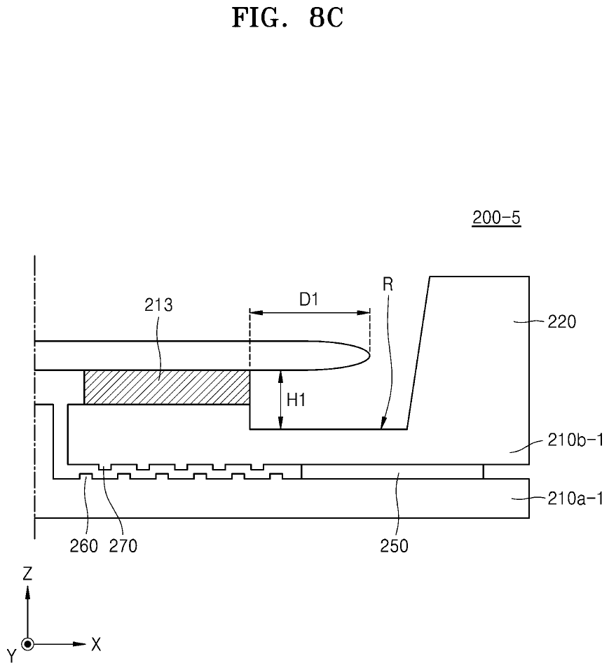

FIG. 8A, FIG. 8B, and FIG. 8C are cross-sectional views illustrating the portion AA of a substrate processing apparatus according to some embodiments. Hereinafter, redundant descriptions of the heater 200-2 described with reference to FIG. 7 and heaters 200-3, 200-4, and 200-5 of FIG. 8A, FIG. 8B, and FIG. 8C are omitted and the differences therebetween are mainly described.

Referring to FIG. 8A, the heater 200-3 may include the first body 210a and a second body 210b-1. A protrusion protruding in the vertical direction Z may be formed on the central portion of the first body 210a. Accordingly, an upper surface of an outer portion of the first body 210a may have a low level in the vertical direction Z, lower than an upper surface of a central portion thereof. The upper surface of the outer portion of the first body 210a having the low level may be disposed below the second body 210b-1. The upper surface of the outer portion of the first body 210a may have a flat shape. A fifth protrusion 270 protruding in the vertical direction Z toward the first body 210a may be formed on a lower surface of the second body 210b-1. The fifth protrusion 270 protruding in the vertical direction Z toward the upper surface of the outer portion of the first body 210a may be formed on the lower surface of the second body 210b-1. A plurality of fifth protrusions 270 may be provided along the lower surface of the second body 210b-1.

The lower surface of the second body 210b-1 may contact the upper surface of the outer portion of the first body 210a. At portions where the fifth protrusion 270 of the second body 210b-1 contacts the upper surface of the outer portion of the first body 210a, a contact area may be small, and thus, heat transfer may be reduced.

The contact area between the upper surface of the first body 210a and the lower surface of the second body 210b-1 may be adjusted by adjusting the number of fifth protrusions 270 of the second body 210b-1. The contact area between the upper surface of the first body 210a and the lower surface of the second body 210b-1 may be adjusted by adjusting the area of the fifth protrusions 270. Accordingly, the heat transfer from the first body 210a to the second body 210b-1 may be adjusted.

Referring to FIG. 8B, the heater 200-4 may include a first body 210a-1 and the second body 210b. A fourth protrusion 260 protruding in the vertical direction Z toward the second body 210b may be formed on the upper surface of the outer portion of the first body 210a-1. The fourth protrusion 260 protruding in the vertical direction Z toward the lower surface of the second body 210b may be formed on the upper surface of the outer portion of the first body 210a-1. A plurality of fourth protrusions 260 may be provided along the upper surface of the outer portion of the first body 210a-1.

The lower surface of the second body 210b may have a flat shape. As the first body 210a-1 and the second body 210b contact each other, the fourth protrusion 260 of the first body 210a-1 and the lower surface of the second body 210b may in contact with each other.

A contact area between the upper surface of the outer portion of the first body 210a-1 and the second body 210b may be the same as the area of the fourth protrusion 260. Heat transfer from the first body 210a-1 to the second body 210b may be adjusted by adjusting the area of the fourth protrusion 260. Heat transfer from the first body 210a-1 to the second body 210b may be adjusted by adjusting the number of the fourth protrusions 260. Accordingly, the heat transfer from the first body 210a-1 to the second body 210b may be adjusted.

Referring to FIG. 8C, the heater 200-5 may include the coupling pad 250, the first body 210a-1, and a second body 210b-1. The fourth protrusion 260 protruding in the vertical direction Z toward the second body 210b-1 may be formed on the upper surface of the first body 210a-1. The fifth protrusion 270 protruding in the vertical direction Z toward the first body 210a-1 may be formed on the lower surface of the second body 210b-1.

The fourth protrusion 260 and the fifth protrusion 270 may be formed to cross each other in the vertical direction Z. That is, the fourth protrusion 260 and the fifth protrusion 270 may not directly face each other in the vertical direction Z. Accordingly, the fourth protrusion 260 and the fifth protrusion 270 may mesh with each other.

The coupling pad 250 may be configured to couple the first body 210a-1 to the second body 210b-1. In addition, heat transfer from the first body 210a-1 to the second body 210b-1 may be adjusted by a coefficient of thermal conductivity of the coupling pad 250.

The fourth protrusion 260 may be formed on the first body 210a-1 and the fifth protrusion 270 may be formed on the second body 210b-1, the first body 210a-1 and the second body 210b-1 may be in contact with each other by the fourth protrusion 260 and the fifth protrusion 270. Thus, the area of the contact surface between the first body 210a-1 and the second body 210b-1 may be the same as the area of the fourth protrusion 260 and the fifth protrusion 270. Accordingly, heat applied to the outer portion of the substrate W may be reduced by reducing heat transfer from the first body 210a-1 to the second body 210b-1. In addition, the heat transfer to the second body 210-b may be adjusted by adjusting the numbers of the fourth protrusions 260 and the fifth protrusions 270.

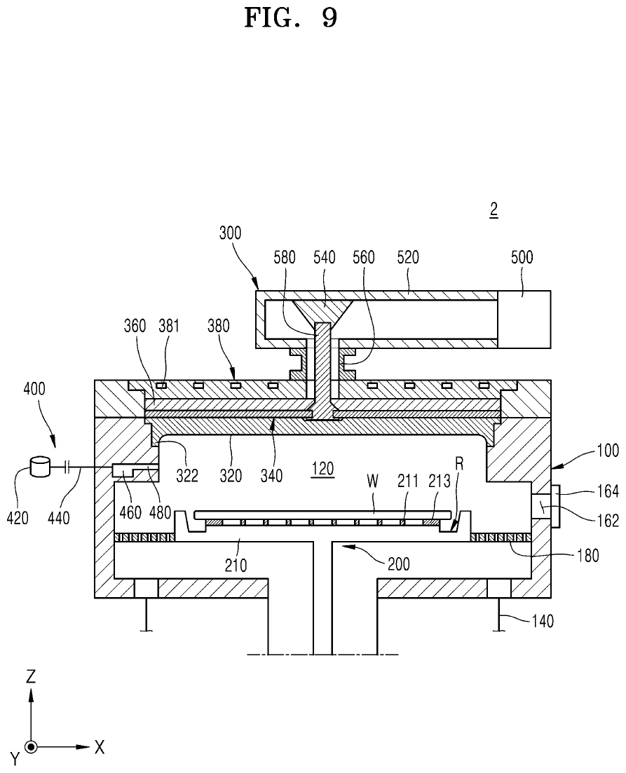

FIG. 9 is a schematic cross-sectional view of a substrate processing apparatus according to some embodiments. Hereinafter, redundant descriptions of the substrate processing apparatus 1 described with reference to FIG. 1, FIG. 2, and FIG. 3 and a substrate processing apparatus 2 of FIG. 9 may be omitted and the differences therebetween are mainly described.

Referring to FIG. 9, the substrate processing apparatus 2 may include a process chamber 100, the heater 200, a microwave application unit 300, and a gas supply unit 400. A processing space 120 configured for processing the substrate W may be formed inside the process chamber 100. A carry inlet 162 may be formed in the sidewall of the process chamber 100. The carry inlet 162 may be opened and closed by a door 164. The carry inlet 162 may enable the substrate W to be moved into, and out of, the process chamber 100.

The heater 200 may support the substrate W within the processing space 120. According to some embodiments, the substrate W may be supported by the first protrusion 211 and the second protrusion 213 formed on the body 210 of the heater 200. This is substantially the same as, or similar to, that described with reference to FIGS. 1 to 7, FIG. 8A, FIG. 8B, and FIG. 8C.

In some embodiments, the heater 200 may support the substrate W with an electrostatic force. Optionally, the heater 200 may support the substrate W by mechanical clamping.

A heating member for heating the substrate W may be provided in the heater 200. In some embodiments, the heating member may be a hot wire disposed inside the heater 200.

The gas supply unit 400 may supply a processing gas to the processing space 120. The processing gas may include hydrogen. The gas supply unit 400 may include a gas supply source 420 and a gas supply line 440. The gas supply source 420 may be coupled to the sidewall of the process chamber 100 by the gas supply line 440. In some embodiments, a buffer space 460 may be provided on the sidewall of the process chamber 100. The buffer space 460 may have, for example, a ring shape. The gas supply line 440 may supply a processing gas to the buffer space 460. A discharge line 480 may extend from the buffer space 460. The discharge line 480 may discharge gas to the processing space 120. The discharge line 480 may be formed in the sidewall of the process chamber 100. A plurality of discharge lines 480 may be provided along the circumference of the side surface of the process chamber 100.

An exhaust line 140 may be connected to the lower wall of the process chamber 100. A pump may be connected to the exhaust line 140. The pump may be configured to adjust the pressure within the processing space 120 to a process pressure. An exhaust baffle 180 may be provided on the side portion of the heater 200 in the processing space 120. The exhaust baffle 180 may have a ring shape. An inner surface of the exhaust baffle 180 may contact the heater 200 and the outer surface of the exhaust baffle 180 may contact the sidewall of the process chamber 100. Gas may be uniformly exhausted from a space above the exhaust baffle 180 to a space below the exhaust baffle 180.

The microwave application unit 300 may include a transmission plate 320, an antenna plate 340, a dielectric plate 360, and an upper plate 380. The microwave application unit 300 may be provided with power by a power source 500. The microwave application unit 300 may apply energy to the processing space 120 of the process chamber 100 to excite gas within the processing space 120 into a plasma. The microwave application unit 300 may excite a process gas and/or a passivation gas to generate plasma. Plasma excited from the process gas may include hydrogen radicals.

The transmission plate 320 may include a quartz material. In some embodiments, the transmission plate 320 may be include a dielectric material such as aluminum oxide (Al₂O₃), aluminum nitride (AlN), sapphire, or a ceramic such as silicon nitride (SiN). The transmission plate 320 may function as an upper wall of the processing space 120. The transmission plate 320 may transmit microwaves into the processing space 120. In some embodiments, an upper surface of the transmission plate 320 may have a flat plate shape. In addition, a central region of a lower surface of the transmission plate 320 may be flat, and an edge region thereof may have a downward protruding shape. In some embodiments, a protrusion or groove may be formed on or in a central region of the lower surface of the transmission plate 320.

The antenna plate 340 may be disposed on the upper surface of the transmission plate 320. The antenna plate 340 may have a disc shape. In some embodiments, the antenna plate 340 may be disposed on the upper surface of the transmission plate 320 and contact the transmission plate 320. In some embodiments, the antenna plate 340 may be spaced apart from the transmission plate 320 by a certain distance. The antenna plate 340 may be formed of a metal material. According to some embodiments, the antenna plate 340 may be formed of a copper or aluminum material. A surface of the antenna plate 340 may be plated with gold or silver.

The dielectric plate 360 may be disposed on an upper portion of the antenna plate 340. The wavelength of microwaves may be changed by the dielectric plate 360. The dielectric plate 360 may include a quartz material. Optionally, the dielectric plate 360 may be formed of a ceramic dielectric material such as aluminum oxide (Al₂O₃), aluminum nitride (AlN), sapphire, or silicon nitride (SiN). In some embodiments, the dielectric plate 360 and the transmission plate 320 may be formed of the same material. In some embodiments, the dielectric plate 360 may be formed of a material different from that of the transmission plate 320. The dielectric plate 360 may have a disc shape. An upper surface and a lower surface of the dielectric plate 360 may be flat. The dielectric plate 360 may be disposed in contact with the antenna plate 340. In some embodiments, the dielectric plate 360 may be spaced apart from the antenna plate 340 by a certain distance.

The upper plate 380 may be disposed on an upper surface of dielectric plate 360. The upper plate 380 may include a metal material. In some embodiments, the upper plate 380 may include an aluminum material. In some embodiments, the upper plate 380 may be provided as a cooling plate. The upper plate 380 may cool the dielectric plate 360, the antenna plate 340, and the transmission plate 320. A cooling passage 381 may be formed inside the upper plate 380. A cooling water may be supplied through the cooling passage 381. The cooling water supplied to the cooling passage 381 may cool the dielectric plate 360, the antenna plate 340, and the transmission plate 320.

The power source 500 may supply power to the microwave application unit 300, which may generate microwaves. In some embodiments, microwaves generated by the microwave application unit 300 may have a frequency in a range of about 23 GHZ to about 26 GHZ. Microwaves may be transferred through a waveguide 520. The waveguide 520 may have a tubular shape of a polygonal vertical cross-section. The inner surface of the waveguide 520 may be provided in a conductor. In some embodiments, the inner surface of the waveguide 520 may be formed of gold or silver.

A coaxial converter 540 may be disposed inside the waveguide 520. The coaxial converter 540 may be located on away from of the power source 500. One end of the coaxial converter 540 may be fixed to the inner surface of the waveguide 520. The coaxial converter 540 may have a cone shape in which a cross-sectional area of a lower end is smaller than that of an upper end. The microwaves transferred through the inner space of the waveguide 520 may be directed downward by the coaxial converter 540.

The microwaves may be transferred to an antenna through an external conductor 560 and an internal conductor 580. The external conductor 560 may be located between the waveguide 520 and the upper plate 380. In some embodiments, an upper end of the external conductor 560 may contact the waveguide 520 and a lower end thereof may contact the upper plate 380. A space formed inside the external conductor 560 may be connected to the inner space of the waveguide 520. The internal conductor 580 may be located inside the external conductor 560. The internal conductor 580 may be provided in a rod shape, and its longitudinal direction may be in the vertical direction Z. An outer surface of the internal conductor 580 may be spaced apart from an inner surface of the external conductor 560.

An upper portion of the internal conductor 580 may be fixed to a lower portion of the coaxial converter 540. The internal conductor 580 may extend in the vertical direction Z. The lower portion of the internal conductor 580 may be coupled to and fixed to a central portion of the antenna plate 340. The internal conductor 580 may be disposed perpendicular to the upper surface of the antenna plate 340. The internal conductor 580 and the external conductor 560 may be disposed coaxially.

Microwaves propagated to the antenna plate 340 in the vertical direction Z may propagate in a radial direction of the dielectric plate 360, and may be transmitted into the processing space 120 through slots formed in the antenna plate 340 and the transmission plate 320. The process gas supplied into the process chamber 100 may be excited into a plasma state by the electric field of microwaves transmitted into the processing space 120.

The upper surface of the substrate W may be heated by plasma formed on the upper portion the substrate W. As the upper surface of the substrate W is heated, the substrate W may be deformed into a convex shape in which the outer portion of the substrate W may be warped downward and the central portion thereof may rise upward. At this time, even if the outer portion of the substrate W is warped downward, the substrate W may not contact the body 210 of the substrate W due to the first recess R formed in the body 210 of the heater 200. Accordingly, no particles may be generated from the substrate W due to contact with the body, and a particle defect may be prevented.

In a case where the second protrusion 213 has a ring shape, an area of the second protrusion 213 may be larger than an area of the first protrusion 211. Thus, the amount of heat applied to the outer portion of the substrate W by the second protrusion 213 may be larger than the amount of heat applied to the central portion of the substrate W by the first protrusion 211. The greater heat applied to the outer portion of the substrate W may compensate for the greater heat loss at the outer portion. Accordingly, warpage of the substrate W may be reduced or eliminated.

Therefore, even if heat loss occurs in the outer portion of the substrate W, heat may be provided to the substrate W such that the central portion and the outer portion of the substrate W may have uniform temperature. Further, the substrate W may be heated uniformly. Accordingly, the thickness of a material deposited on the substrate W may be uniform.

While the inventive concept has been particularly shown and described with reference to embodiments thereof, it will be understood that various changes in form and details may be made therein without departing from the spirit and scope of the following claims.

What is claimed is:

1. A substrate processing apparatus comprising:
a process chamber comprising a processing space;
a heater located inside the process chamber and configured to heat a lower portion of the processing space;
a first heat source located inside the process chamber and spaced apart from the heater and configured to heat an upper portion of the processing space;
a plurality of first protrusions protruding in a vertical direction from an upper surface of the heater; and
a second protrusion protruding in the vertical direction from an edge portion of the upper surface of the heater.

2. The substrate processing apparatus of claim 1, wherein the heater extends in a horizontal direction and the plurality of first protrusions and the second protrusion extend from an upper surface of the heater,
wherein the heater has a recess formed in the upper surface of the heater, and
wherein the recess is formed outside the plurality of first protrusions and the second protrusion in the upper surface of the heater.

3. The substrate processing apparatus of claim 2, wherein a distance from the upper surface of the heater where the recess is formed to an upper surface of the second protrusion is in a range of about 25 micrometers (μm) to about 35 μm.

4. The substrate processing apparatus of claim 2, wherein the recess has a ring shape when viewed from the vertical direction.

5. The substrate processing apparatus of claim 1, wherein the first heat source includes a microwave application unit.

6. The substrate processing apparatus of claim 1, wherein the second protrusion has a ring shape when viewed from the vertical direction.

7. The substrate processing apparatus of claim 6, wherein
the heater further comprises a third protrusion protruding from the upper surface of the heater in the vertical direction and formed inside the second protrusion, and
the third protrusion has a ring shape when viewed from the vertical direction.

8. The substrate processing apparatus of claim 1, wherein a horizontal distance from an outer surface of the second protrusion to a side surface of a substrate disposed on the heater is in a range of about 2400 micrometers (μm) to about 3000 μm.

9. The substrate processing apparatus of claim 1, wherein
the heater includes a first body and a second body coupled to and separated from each other,
the first body includes a lower portion and a central portion of the heater,
the second body includes an upper outer portion of the heater,
the first body and the second body are coupled to each other by a contact pad, and
the second protrusion is formed on an upper surface of the second body.

10. The substrate processing apparatus according to claim 9, wherein
a recess is formed in the second body extending in the vertical direction from the upper surface the second body toward a lower surface of the second body, and
the recess is formed outside the second protrusion.

11. The substrate processing apparatus according to claim 9, further comprising:
a fourth protrusion protruding in the vertical direction toward the second body is formed on an upper surface of a lower portion of the first body, and
a fifth protrusion protruding in the vertical direction toward the first body is formed on a lower surface of the second body.

12. A substrate processing apparatus comprising:
a process chamber comprising a processing space;
a microwave application unit located in an upper portion of the processing space; and
a heater located inside the process chamber and configured to heat a lower portion of the processing space,
wherein the heater comprises a body extending in a horizontal direction;
a plurality of first protrusions protruding in a vertical direction from an upper surface of the body; and
a second protrusion protruding in the vertical direction from an edge portion of the upper surface of the body,
wherein the second protrusion defines a central portion of the body and an outer portion of the body opposite to the central portion when viewed from the vertical direction, and
the body has a recess formed in the upper surface of the body in the outer portion of the body.

13. The substrate processing apparatus of claim 12, wherein the recess has a ring shape when viewed from the vertical direction.

14. The substrate processing apparatus of claim 12, wherein the second protrusion has a ring shape when viewed from the vertical direction.

15. The substrate processing apparatus of claim 12, further comprising a gas supply unit configured to supply a processing gas to the processing space.

16. The substrate processing apparatus of claim 12, wherein
the body further comprises a third protrusion protruding in the vertical direction from the upper surface of the body formed inside the second protrusion, and
the third protrusion has a ring shape when viewed from the vertical direction.

17. The substrate processing apparatus of claim 12, wherein the recess has a concave parabolic shape.

18. A substrate processing apparatus comprising:
a process chamber comprising a processing space for processing a substrate therein;
a heater located inside the process chamber and configured to support and heat a lower surface of the substrate, wherein the heater comprises a body extending in a horizontal direction;
a gas supply unit configured to supply a processing gas to the processing space;
a microwave application unit configured to heat the processing gas supplied to the processing space;
a plurality of first protrusions protruding in a vertical direction from an upper surface of the body; and
a second protrusion protruding in the vertical direction from an edge portion of the upper surface of the body,
wherein the second protrusion a central portion of the body and an outer portion of the body opposite to the central portion when viewed from the vertical direction,
the second protrusion has a ring shape when viewed from the vertical direction,
the body has a recess formed in the upper surface of the body in the outer portion of the body, and
the recess has a ring shape when viewed from the vertical direction.

19. The substrate processing apparatus of claim 18, further comprising a guide wall protruding from an outermost portion of the upper surface of the body in the vertical direction.

20. The substrate processing apparatus of claim 18, wherein
a distance from the upper surface of the body where the recess is formed to the lower surface of the substrate is in a range of about 25 micrometers (μm) to about 35 μm, and
a horizontal distance from an outer surface of the second protrusion to a side surface of the substrate is in a range of about 2400 μm to about 3000 μm.
